(19) United States
(12) Patent Application Publication
(10) Pub. No.: US 2003/0174471 A1
(43) Pub. Date: Sep. 18, 2003

(54) Device for the power supply and the control of electric heating resistances in operating machines

(75) Inventors: Giovanni Tonello, Provaglio D'Iseo (IT); Maurizio Cornali, Bovezzo (IT)

Correspondence Address: AKERMAN SENTERFITT, P.O. BOX 3188, WEST PALM BEACH, FL, 33402-3188, US

(73) Assignee: GEFRAN S.p.A., Provaglio D'Iseo (IT)

(21) Appl. No.: 10/356,057

(22) Filed: Jan. 31, 2003

(30) Foreign Application Priority Data
Jan. 31, 2002 (EP) 02425045.8

(51) Int. Cl. H05K 7/00

(52) U.S. Cl. 361/728

(57) ABSTRACT

The invention relates to a device (1) for the power supply and the control of heating resistors particularly in plastic material working machines, the device being of simple construction, fast installation and maintenance and offering an excellent heat dissipation. This device (1) comprises at least one power module (2) and one control module (3) for each resistor, intended to be mounted on a control board or panel (11) associated to the machine, and a base shell (8), incorporating the control module (3), intended to hold removably the power module (2) to form a structure of structurally independent elements which can be manipulated individually

### DESCRIPTION

1. Field of Application

The present invention relates to a device for the power supply and the control of heating resistors in manufacturing machines in general and in particular in plastic material working machines.

More particularly, the invention relates to such a device comprising at least one power module and one control module for one or more resistors, intended to be mounted on a control board or panel associated to the machine.

2. Prior Art

As it is well known in this specific technical field, plastic material working machines (injection presses, extruders, thermoforming machines, blowing machines, etc.) are equipped with specific command and control devices of the resistors ensuring the heating of the plastic material to be worked. These devices allow the temperature of the areas wherein the plastic material is melted to be accurately thermoregulated, for the total benefit of the machined product quality.

These command and control devices are housed on control boards or panels associated to the machines. It must be noted that each control board or panel can house a power module for each resistor and a control module for one or more resistors. In many applications each control board or panel can house tens of said devices which are assembled and wired by skilled personnel.

The power module generally comprises a solid-state switching relay associated by a heat dissipator, the dissipator being generally formed by a bulky metal element made of aluminium section packed with cooling ribs. The control module comprises a Programmed Logic Control (PLC) to thermoregulate several resistors, or one electronic instrument dedicated to the thermoregulation of a single resistor.

The fast switching of the power module relay, under the control effect of the control module, allows the desired thermoregulation to be implemented ensuring the good quality of the plastics working process.

Generally, on each control board or panel the power modules and the control modules of the control and command devices are housed separately from each other. In practice, all the power modules are mounted side by side in a predetermined portion of the control board; similarly, all the control modules are adjacent to each other on another separate portion of the control board.

This division is mainly due to the need to nest all the dissipators in one area of the control board which can be eventually cooled more easily.

However, it is very evident that this division requires complex harnesses to connect each power module to the corresponding control module.

Consequently, the known control and command devices are satisfactory for many aspects but they do not come to expectation from the point of view of the equipment and maintenance thereof, which are very complex and difficult.

In order to try and overcome these drawbacks and to reduce the wiring times and the board complexity, some manufacturers of these devices have suggested to produce them in the all-in-one form, i.e. providing the control module on the front face of the dissipator associated to the power module.

This solution can initially seem advantageous, but it requires a great production effort, both for conveniently insulating the control module from the dissipator and for housing the harnesses which are bound to reach the control module. This involves considerably high production costs.

In addition, the problem of associating a so-structured device to other accessory devices such as fuses, overload cutouts and the like still remains. The connection to these accessory devices is always performed by means of the above-mentioned complex harnesses.

In this context, the situation is then made much more complex by the fact that, paradoxically, the dissipating element undergoes more frequently failures and malfunctions and a replacement thereof is sometimes required. In all-in-one devices this would lead, however, also to the removal of the expensive control module.

In practice, in the attempt to implement the all-in-one solution, the experts in command and control devices should therefore face a huge number of different circumstances which would hamper them in the standardisation of the solution.

The technical problem underlying the present invention is to provide a device for commanding and controlling the resistors of manufacturing machines in general, for example plastic material working machines, this device presenting an extremely simple structure allowing the production thereof with a minimum number of different complex elements, thus simplifying the composition and assembly of the control board and overcoming the drawbacks mentioned with reference to the solutions provided by the prior art.

In addition, such a device should even improve the thermal dissipation of the dissipator associated to the power module.

### SUMMARY OF THE INVENTION

The solutive idea underlying the present invention is to provide a base shell allowing the power module and corresponding dissipator to be held and incorporating the control module. This shell should also allow the fast coupling of the so-structured control and power supply device on the control board or panel.

Therefore, the base shell comprises all the electronic components required to control of the power module and thermoregulate the heating resistor.

Based on this solutive idea, the technical problem is solved by a device as previously described and defined by the characterising part of claim 1.

The characteristics and advantages of the device according to the invention will be apparent from the following description of an embodiment thereof given by way of non limiting example with reference to the attached drawings.

In the drawings:

### BRIEF DESCRIPTION OF THE DRAWINGS

FIG. 1 is a perspective view of a device according to the present invention;

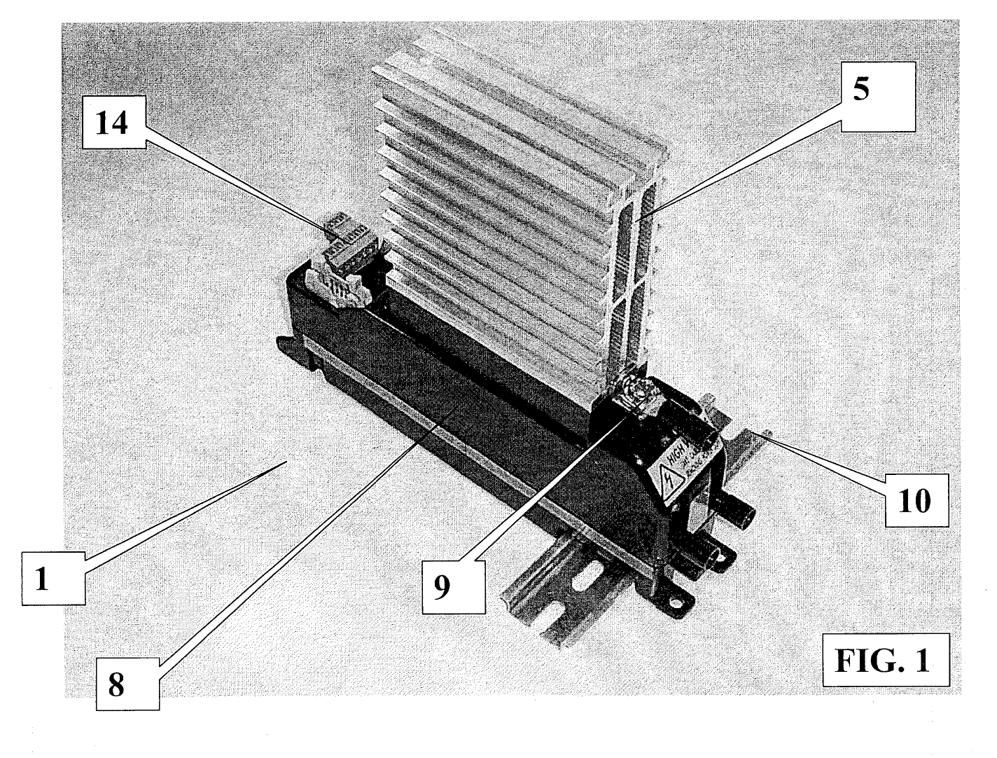

FIG. 2 is a perspective view of the device of FIG. 1, with a part removed and overturned;

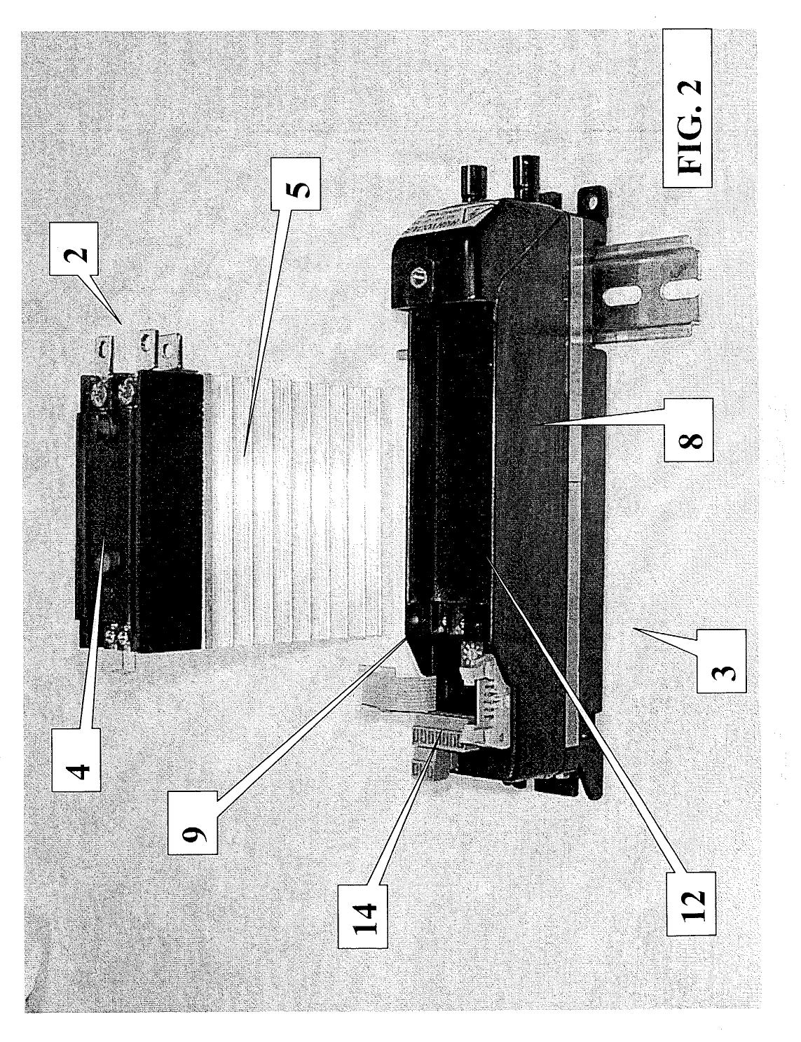

FIG. 3 is a perspective view of a set of devices according to the invention and electrically interconnected to each other;

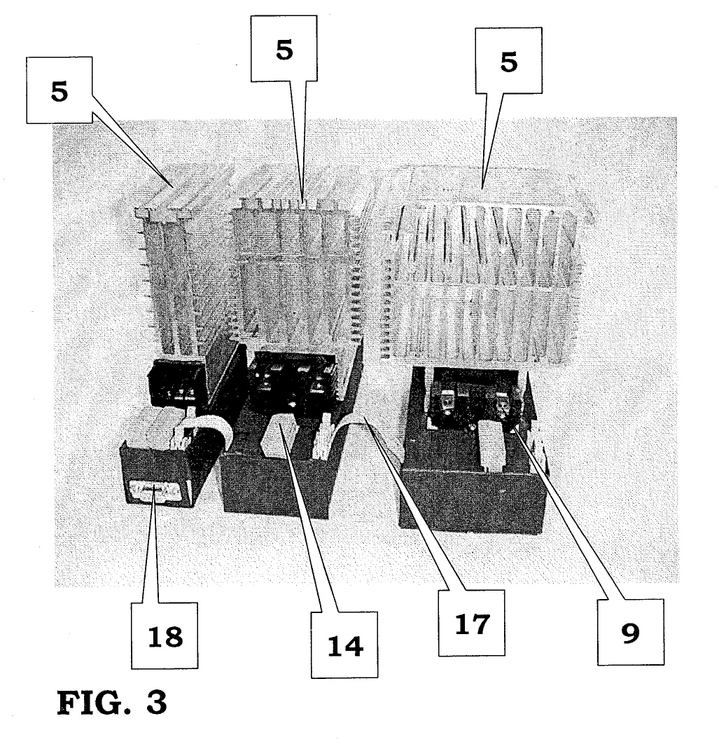

FIG. 4 is a vertical elevation view of the device of FIG. 1 associated to an accessory safety block;

FIG. 5 is a front view from below of the set of devices of FIG. 3 mounted on the control board or panel.

### DETAILED DESCRIPTION

With reference to the drawings, a device according to the present invention for commanding and controlling heating resistors in manufacturing machines in general is generally and schematically indicated with 1.

More particularly, but not exclusively, the device 1 is suitable for manufacturing machines for plastic material working and the following description is given with reference to this field of application only for convenience of illustration. In fact, the device according to the invention can be efficiently applied in a plurality of similar sectors such as for example the rubber treatment field, the packaging field or in furnaces of any nature.

The device 1 comprises a power portion and a control portion. Reference will be made hereafter to the power portion with the term power module 2, while the control portion will be identified with the term control module 3.

The power module 2 comprises a switching relay 4, for example a solid-state relay, which allows the power supply to be switched to a heating resistor of the manufacturing machine for plastics working. The resistor and the manufacturing machine are not shown in the drawings since they are completely conventional.

The power module 2 comprises also an heat dissipator 5 strictly associated to the switching relay 4 to favour the thermal convection. The dissipator 5 comprises traditionally a metal element, in generally pre-formed from an extruded aluminium section packed with perimeter cooling ribs.

Advantageously, according to the invention, the device 1 comprises a base shell 8 incorporating the control module 3 and intended to hold the power module 2. The power module 2 is removably held on the shell 8.

This shell 8 substantially forms a base which allows the power module 2 to be implemented and held on a control board or panel 11 in a predetermined spaced relation with respect to this panel.

The fact of providing the shell 8 as base socket allows the power module 2 and the control module 3 to be associated in an almost all-in-one structure formed by structurally independent elements which can be handled individually.

In order to be easily locked to the panel 11, the shell 8 is equipped with traditional means for the fast coupling to a guide or supporting rail 10 which is worldwide known and standardised for control boards or panels 11. At this purpose, the German rules known with the abbreviation DIN EN 50022 are preferably followed.

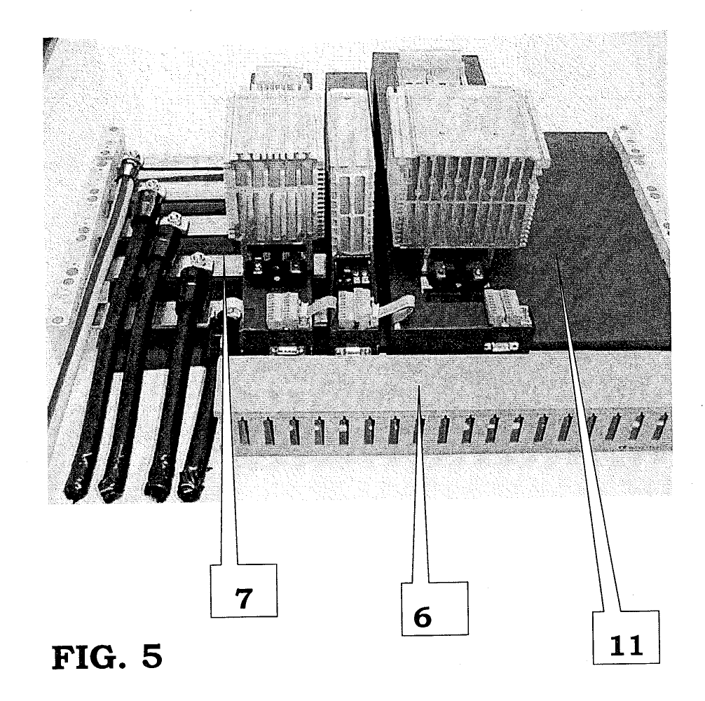

Several shells 8 can be coupled on the same guide 10, the one adjacent to the other. The control boards 11 are wall-mounted or housed in suitable protection boxes in order to be elongated along a vertical plane. FIG. 5 schematically shows an example of command board produced by assembling some devices 1 on a set of copper bars 7 extending parallely to each other and electrically supplied independently from the respective power wires.

Opposed clamps 9 are naturally provided on the shell 8 in order to lock removably the power module 3 and to supply electric power thereto. These clamps 9 receive harnesses emerging from an housing raceway 6 such as the one shown in FIG. 5.

Preferably, the shell 8 has a substantially parallepipedic elongate shape whose width is lower or equal to the width of the power module 2 and, more particularly, to the width of the dissipator 5.

The shell 8 is boxed in order to house conveniently the control module 3 and also possible harnesses or electric interconnection elements.

For completeness of the description, it must be pointed out that the control module 3 can comprise an electronic driving circuit of the relay 4 intended to produce in the relay 4 several high speed commutations to provide or interrupt the power supply to the resistors and allow therefore a thermoregulation of the manufacturing machine heating area.

In practice, the control module 3 incorporates all the most complex functions of the device 1, while some simpler control functions can be left outside the device 1, as it will be apparent from the following description.

Advantageously, the power module 2 is mounted on a front face 12 of the shell 8 so that the dissipator 5 projects from the shell 8. This location allows the natural air convective circulation to ensure an efficient cooling.

A possible optional thermal insulation element, for example an insulating plate, can be provided inside the shell 8 between the modules 2 and 3, below the wall 12.

When the shell 8 is mounted on a guide 10, the longitudinal axis of the shell 8 is perpendicular to the guide 10 and coplanar to the control board or panel 11. The dissipator 5 is therefore mounted frontally and projecting outwards. Moreover, due to the presence of the base shell, the dissipator is located at a predetermined spaced relation with respect to the guide 10 and to the harnesses belonging to the guide. Consequently, the cables and/or possible holding raceways thereof, associated to or running parallely to the guide 10 DIN, are held at a distance from the dissipator which is sufficient not to obstruct the convective flow of the cooling air.

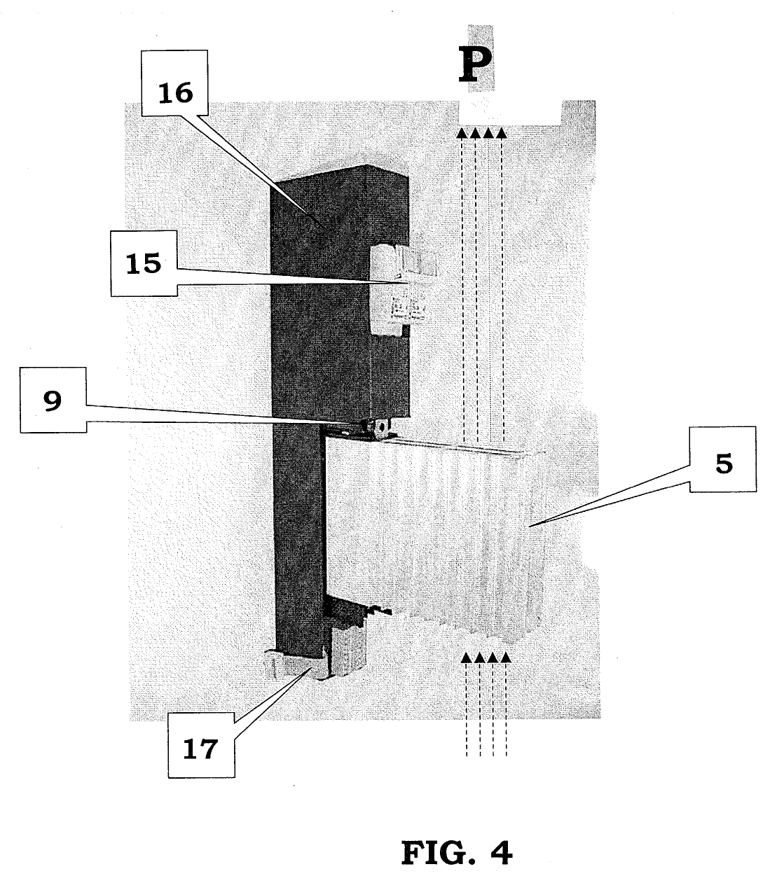

In this way, the natural convection of the cooling air extending from the bottom to the top along the path P avoids the control module 3 to be overheated by the dissipator, as clearly shown in FIG. 4.

According to the invention, the shell 8 also houses a connector 14 for the electric supply of the control module 3. This connector 14 is provided on the front face 12 and allows the control module 3 to be interconnected to electric supply harnesses housed in the raceway 6.

In practice, as it becomes apparent from the above description, the device 1 essentially comprises: the shell 8 which serves as base socket and which incorporates the control module 3, the power module 2 held on the shell 8, the connectors 14 and the clamps 9, forming an all-in-one structure wherein the main elements, i.e. the modules 2 and 3, are structurally independent and can be manipulated individually. In practice, it is easy to remedy to a possible failure or damage of one of the power and control modules through a fast replacement of the damaged module. Therefore, the single replacement of the power module 3 by a greater or lower width module is also easier.

Some particular applications require a protection element both to select or section the device 1 and to protect the electric supply mains it is connected thereto. FIG. 4 shows for example a safety block 15 incorporating a disconnecting fuse which is series-connected to the device 1. Alternatively, a protection device can be provided, for example a magnetothermal protection of the power module 2.

Advantageously, the fact of providing a composite structure comprising the shell 8 and the power module 2 in a single all-in-one device 1 allows a boxed housing structure 16 of the safety block 15 to be also provided, the structure being suitable for modular association by fast clamping by means of an appropriate connector positioned at one end of the shell 8, and as substantial longitudinal prolongation of the device 1.

Further accessory elements of the device 1 could therefore be provided inside a box-structured housing shell 16 such as the one of the safety block 15.

For completeness of the description, it must be pointed out that the control modules 3 can be reciprocally parallel-connected, depending on the users' needs or on the specific application of the control and command device 1, for example by means of a connector included in each shell 8 and to a multiple bus-type electric interconnection 17. These bus 17 can be partially hidden inside the boxed body of the shell 8 and through a side slot provided near the other connector 14.

In addition, in order to allow each device 1 to be connected to a computerised control system, not shown since conventional, a further serial or parallel connector 18 is provided, the connector being mounted on one end of the shell 8 and connected inside the control module 3.

The device according to the invention efficiently solves the technical problem and it achieves several advantages, the first being certainly the fact of comprising a minimum number of different complex elements, due to the fact that the power and control modules are of the traditional type and in the strictly necessary number.

A further advantage is the command board or panel simplicity, due to the fact that it must house a few simple elements just like the devices according to the invention.

Finally, it is worth noting that the device according to the invention is fit for an easy part replacement due to failures or periodic maintenance; it allows an efficient thermal dissipation and a considerable simplicity in the electric connections between the modules of different resistors.

1. Device (1) for the power supply and the control of heating resistors in manufacturing machines in general and in particular in plastic material working machines, comprising at least one power module (2) and one control module (3) for each resistor, intended to be mounted on a control board or panel (11) associated to the machine, characterised in that it comprises a shell (8) incorporating said control module (3) and intended to hold said power module (3), forming a structure of structurally independent elements which can be manipulated individually.

2. Device according to claim 1, characterised in that said power module (2) is removably held by said shell (8).

3. Device according to claim 1, characterised in that the shell (8) is boxed and substantially parallelepiped-shaped, the width thereof being lower or equal to the power module width.

4. Device according to claim 1, characterised in that the shell (8) is mounted on DIN guides of said panel (11), the longitudinal axis being located vertically.

5. Device according to claim 1, characterised in that it comprises a first connector (14) for the power supply to said control module (3) in order to fix some harnesses housed in a raceway (6) associated to the control panel (11).

6. Device according to claim 5, characterised in that it comprises an electric bus-type interconnection for connecting in parallel several adjacent control modules (3).

7. Device according to claim 1, characterised in that it comprises at one end of the shell (8) a serial connector (18) connected to the control module (3).

8. Device according to claim 1, characterised in that it comprises also a safety block (15) housed in a boxed body (16) being modularly associated to the device (1) in alignment along the longitudinal axis of said structure.

9. Device according to claim 8, characterised in that said safety block (15) comprises a disconnecting fuse or a protection device of said power module (2).

10. Device according to claim 1, characterised in that said shell comprises fast coupling means to a support rail or guide (10).
